(19) United States
(12) Patent Application Publication
(10) Pub. No.: US 2013/0336873 A1
(43) Pub. Date: Dec. 19, 2013

(54) DIAMOND GROWTH USING DIAMONDOIDS

(71) Applicants: Hitoshi Ishiwata, Stanford, CA (US); Zhi-Xun Shen, Stanford, CA (US); Nicholas A. Melosh, Stanford, CA (US); Jeremy Dahl, Stanford, CA (US)

(72) Inventors: Hitoshi Ishiwata, Stanford, CA (US); Zhi-Xun Shen, Stanford, CA (US); Nicholas A. Melosh, Stanford, CA (US); Jeremy Dahl, Stanford, CA (US)

(21) Appl. No.: 13/837,138

(22) Filed: Mar. 15, 2013

Related U.S. Application Data
(60) Provisional application No. 61/660,725, filed on Jun. 16, 2012.

(51) Int. Cl. C30B 25/18; C30B 29/04

(52) U.S. Cl. CPC C30B 25/18; C30B 29/04
USPC 423/446; 117/95

(57) ABSTRACT

Methods of growing diamond and resulting diamond nanoparticles and diamond films are described herein. An example of a method of growing diamond includes: (1) anchoring diamondoids to a substrate via chemical bonding between the diamondoids and the substrate; (2) forming a protective layer over the diamondoids; and (3) performing chemical vapor deposition using a carbon source to induce diamond growth over the protective layer and the diamondoids.

### CROSS-REFERENCE TO RELATED APPLICATION

This application claims the benefit of U.S. Provisional Application Ser. No. 61/660,725 filed on Jun. 16, 2012, the disclosure of which is incorporated herein by reference in its entirety.

### STATEMENT REGARDING FEDERALLY SPONSORED RESEARCH OR DEVELOPMENT

This invention was made with Government support under contract DE-AC02-765F00515 awarded by the Department of Energy. The Government has certain rights in this invention.

### FIELD OF THE INVENTION

The invention generally relates to diamond growth and, more particularly, to diamond growth using diamondoids.

### BACKGROUND

Aside from its exceptional beauty, diamond possesses other desirable characteristics, including its mechanical hardness, thermal conductivity, high refractive index, and wide band gap. These characteristics can be leveraged for a number of practical applications. For example, mechanical hardness of diamond can be exploited as coatings for electronic devices, glasses, high end watches and jewelries, chemical-mechanical polishing tools, drills, and cutting tools. Thermal conductivity with little or no electrical conductivity is a useful characteristic for addressing heat dissipation bottleneck in electronic devices from laptops to light emitting diodes (“LEDs”). The high refractive index of diamond can be exploited in fiber optics for information processing and anti-reflection coatings of optical devices such as solar cells. Wide band gap, unusual surface characteristics, and high endurance of diamond can be exploited in power electronic devices and photocathodes operating under harsh environments. The wide band gap of diamond allows stable quantum states to be produced by a doping and annealing process, leading to doped nanostructures useful for quantum information processing, high resolution magnetic field measurements for next generation memory devices metrology, and life science and drug delivery applications.

Despite its tremendous potential, the introduction of diamond into practical applications has been hampered by difficulties in material synthesis. Attempts to achieve diamond growth include a seeding technique using ultra-dispersed diamonds (“UDDs”), which are particles of diamond with sizes on the order of about 10 nm formed by detonation of an oxygen-deficient mixture in a closed chamber. Unfortunately, diamond particles formed by detonation can have non-uniform sizes and significant surface defects, and a concentration of nitrogen and other impurities in the particles is often not well controlled. Also, UDD seeding typically involves abrasion against a substrate by ultra-sonication or mechanical scratching. Such an invasive process is unsuitable for electronic devices, and can produce defective grain boundaries for phonon transport and can adversely impact thermal transport characteristics. Moreover, UDD seeding has failed to achieve a sufficiently high seeding density, and uniformity of diamond growth can be lacking as a result of the use of intrinsically defective seeding particles.

It is against this background that a need arose to develop the fabrication methods and related devices described herein.

### SUMMARY

Embodiments of this disclosure relate to the use of diamondoids as seeding agents or molecules for growth of diamond nanoparticles and diamond films. In some embodiments, diamondoids are chemically functionalized to allow covalent bonding to silicon, metal, oxide, and other types of surfaces, allowing the diamondoids to remain intact at diamond growth temperatures and act as nucleation sites. Since diamondoids are not produced from detonation, these seeding agents can be substantially nitrogen-free, substantially graphite-free, and substantially free of surface defects.

In some embodiments, chemically functionalized diamondoids are used as seeding agents to initiate growth of ultra-small diamond nanoparticles. Seeded substrates are subjected to Plasma Enhanced Chemical Vapor Deposition (“PECVD”) for nucleation and growth of diamond nanoparticles. Different structures and sizes of diamondoids can be used to achieve a seeding effect. The resulting diamond nanoparticles can have sizes below about 5 nm, with a high degree of uniformity in sizes, and a high seeding density exceeding about 5×10¹² cm⁻² in some embodiments. In addition, diamond nanoparticles with Nitrogen-Vacancy (“NV”) centers can be formed using diamondoid seeding, followed by nitrogen implantation and annealing. Ultra-small diamond nanoparticles formed using diamondoid seeding can have a wide range of practical applications, such as in fine particle polishing for semiconductors, fine cutting tools, tribology, drug delivery, bio-imaging, tissue engineering, quantum information processing, and metrology. For example, optical properties of diamond nanoparticles with NV centers, with their bio-compatibility, can be used for bio-sensing, bio-imaging, diagnostics, and drug delivery.

In other embodiments, monolayers of chemically functionalized diamondoids are covalently bonded onto substrates as seed layers to grow ultra-thin diamond films. This seeding technique can avoid the use of abrasion against a substrate. Moreover, chemical functionalization can reduce scattering at grain boundaries, yielding a high thermal conductivity interface and attaining greater benefit of diamond's superior thermal conductivity for heat dissipation applications. Using diamondoid seeding, diamond films can be formed on substrates by PECVD at moderate temperatures, such as at or below about 360° C. or at or below about 300° C., rendering this seeding technique compatible with electronic devices. Both Raman spectroscopy and Transmission Electron Microscopy (“TEM”) analysis demonstrate the formation of high-quality crystalline diamond that is substantially defect-free, continuous, and conformal. Scanning Tunneling Microscopy (“STM”) analysis reveals that a seeding density attained in some embodiments can exceed about 10¹² cm⁻², which allows uniform growth of diamond films with a reduced thickness, such as in the range of about 10 nm to about 20 nm. The ultra-high seeding density and the resulting uniformity and continuity of the diamond films allow a desired thermal, mechanical, or other effect to be attained with a reduced thickness of the films, thus reducing a growth time by an order of magnitude or more in some embodiments. Furthermore, a size and a shape of diamondoid molecules can be selected to control a crystalline orientation of a diamond film. Resulting diamond films can be used to address the heat dissipation problem that is encountered in a number of microelectronic devices, by using diamond as a heat sink and using a growth technique that is compatible with complementary metal-oxide-semiconductor (“CMOS”) technology and other semiconductor processing technologies. The growth technique also can allow the incorporation of diamond into microelectromechanical system (“MEMS”) devices, bio-sensors, and photonic crystal structures.

One aspect of this disclosure relates to a method of growing diamond. In one embodiment, the method includes: (1) anchoring diamondoids to a substrate via chemical bonding between the diamondoids and the substrate; (2) forming a protective layer over the diamondoids; and (3) performing chemical vapor deposition using a carbon source to induce diamond growth over the protective layer and the diamondoids.

Another aspect of this disclosure relates to a diamond nanoparticle or a population of diamond nanoparticles. In one embodiment, the population of diamond nanoparticles is formed by: (1) anchoring diamondoids to a substrate via chemical bonding between the diamondoids and the substrate; (2) forming a protective layer over the diamondoids; and (3) performing chemical vapor deposition using a carbon source to induce diamond growth over the protective layer and the diamondoids.

A further aspect of this disclosure relates to a diamond film. In one embodiment, the diamond film is formed by: (1) anchoring diamondoids to a substrate via chemical bonding between the diamondoids and the substrate; (2) forming a protective layer over the diamondoids; and (3) performing chemical vapor deposition using a carbon source to induce diamond growth over the protective layer and the diamondoids.

Other aspects and embodiments of the invention are also contemplated. The foregoing summary and the following detailed description are not meant to restrict the invention to any particular embodiment but are merely meant to describe some embodiments of the invention.

### BRIEF DESCRIPTION OF THE DRAWINGS

For a better understanding of the nature and objects of some embodiments of the invention, reference should be made to the following detailed description taken in conjunction with the accompanying drawings.

FIG. 1 shows lower diamondoids, namely adamantane, diamantane, and triamantane.

FIG. 2 shows selected examples of higher diamondoids.

FIG. 3 shows selected examples of apical-functionalized diamondoids and medial-functionalized diamondoids.

FIG. 4A, FIG. 4B, FIG. 4C, and FIG. 4D show a sequence of operations of a method of growing diamond.

FIG. 5 shows an example of chemical bonding between silanol groups of diamondoids and hydroxy groups exposed on an oxidized silicon surface.

FIG. 6 shows an example of chemical bonding between phosphoryl groups of diamondoids and hydroxy groups exposed on an oxide surface.

FIG. 7 shows a Scanning Electron Microscopy (“SEM”) image and a Raman spectrum of diamonds that were grown over a silicon substrate.

FIG. 8 shows images comparing diamond growth using thiol-functionalized diamantane (d) as a seeding molecule, versus other forms of carbon as seeding molecules (a)-(c).

FIG. 9 shows images comparing diamond growth using adamantane as a seeding molecule, versus UDD seeding.

FIG. 10 shows images of a substantially pinhole-free diamond film formed after about 1 hour of CVD growth.

FIG. 11 shows STM images of monolayers of thiol-functionalized diamondoids formed over Au substrates.

FIG. 12 shows results of TEM and micro diffraction analysis, which confirm the formation of diamond nanoparticles.

FIG. 13 shows superimposed Fourier Transform Infrared (“FTIR”) spectra to confirm presence of diamondoid after TiO₂ coating.

FIG. 14 shows images comparing diamond growth using apical-functionalized diamantane versus medial-functionalized diamantane as seeding molecules.

FIG. 15 shows images comparing diamond growth using apical-functionalized tetramantane versus basal-functionalized pentamantane as seeding molecules. Tetramantane does not quite form a film, but pentamantane shows ultra-thin film formation with small cracks.

FIG. 16 shows a bright field image of diamond growth on a SiO₂ window grid using diamondoid seeding.

FIG. 17 shows a TEM image of diamond growth using diamondoid seeding. Seeding density was about 5×10¹² cm³, and resulting nanoparticles have an average diameter of about 3.97±0.4 nm.

FIG. 18 shows an image of diamond nanoparticles after implantation with nitrogen and annealing. Photoluminescence spectrum shows an extremely high intensity peak at about 637 nm, indicating NV-state inside diamond nanoparticles grown from diamondoids.

FIG. 19 shows results of Electron Energy Loss Spectroscopy (“EELS”) analysis, which confirm the formation of diamond nanoparticles.

FIG. 20 shows a X-ray Diffraction (“XRD”) spectrum obtained from diamond grown on a tungsten substrate using diamantane functionalized with phosphoric dichloride.

### DETAILED DESCRIPTION

### Definitions

The following definitions apply to some of the aspects described with respect to some embodiments of this disclosure. These definitions may likewise be expanded upon herein.

As used herein, the singular terms “a,” “an,” and “the” include plural referents unless the context clearly dictates otherwise. Thus, for example, reference to an object can include multiple objects unless the context clearly dictates otherwise.

As used herein, the term “set” refers to a collection of one or more objects. Thus, for example, a set of objects can include a single object or multiple objects. Objects of a set can also be referred to as members of the set. Objects of a set can be the same or different. In some instances, objects of a set can share one or more common characteristics.

As used herein, the term “aspect ratio” refers to a ratio of a largest dimension or extent of an object and an average of remaining dimensions or extents of the object, where the remaining dimensions are orthogonal with respect to one another and with respect to the largest dimension. In some instances, remaining dimensions of an object can be substantially the same, and an average of the remaining dimensions can substantially correspond to either of the remaining dimensions. For example, an aspect ratio of a cylinder refers to a ratio of a length of the cylinder and a cross-sectional diameter of the cylinder. As another example, an aspect ratio of a spheroid refers to a ratio of a major axis of the spheroid and a minor axis of the spheroid.

As used herein, the term “size” refers to a characteristic dimension of an object. Thus, for example, a size of an object that is spherical can refer to a diameter of the object. In the case of an object that is non-spherical, a size of the non-spherical object can refer to a diameter of a corresponding spherical object, where the corresponding spherical object exhibits or has a particular set of derivable or measurable characteristics that are substantially the same as those of the non-spherical object. Thus, for example, a size of a non-spherical object can refer to a diameter of a corresponding spherical object that exhibits optical characteristics that are substantially the same as those of the non-spherical object. Alternatively, or in conjunction, a size of a non-spherical object can refer to an average of various orthogonal dimensions of the object. Thus, for example, a size of an object that is a spheroidal can refer to an average of a major axis and a minor axis of the object. When referring to a set of objects as having a particular size, it is contemplated that the objects can have a distribution of sizes around the particular size. Thus, as used herein, a size of a set of objects can refer to a typical size of a distribution of sizes, such as an average size, a median size, or a peak size.

As used herein, the term “nanostructure” refers to an object that has at least one dimension in the range of about 0.5 nm to about 100 nm, such as from about 0.5 nm to about 50 nm, from about 0.5 nm to about 20 nm, from about 0.5 nm to about 10 nm, from about 0.5 nm to about 5 nm, or less than about 5 nm. A nanostructure can have any of a wide variety of shapes, and can be formed of a wide variety of materials.

As used herein, the term “nanoparticle” refers to a spherical or spheroidal nanostructure. Typically, each dimension of a nanoparticle is in the range of about 0.5 nm to about 100 nm, the nanoparticle has a size in the range of about 0.5 nm to about 100 nm, and the nanoparticle also has an aspect ratio that is less than about 5, such as no greater than about 3, no greater than about 2, no greater than about 1.5, or about 1.

### Diamond Growth Using Diamondoid Seeding

Embodiments of this disclosure relate to the use of diamondoids for seeded growth of diamond nanoparticles and diamond films. Diamondoids refer to bridged-ring cycloalkanes, which can include sp³ hybridized carbon atoms, and carbon arrangements that are superimposable on a fragment of a face-centered cubic diamond crystalline lattice. As such, diamondoids can be viewed as molecular-scale fragments of diamond, and can have sizes spanning a range between small molecules and larger diamond particles, such as in the range of about 0.5 nm to about 2 nm. Diamondoids can be extracted and purified from petroleum, and, unlike UDDs, diamondoids can be substantially free of impurities, such as nitrogen and graphite, can be substantially free of surface defects, and can be substantially uniformly sized.

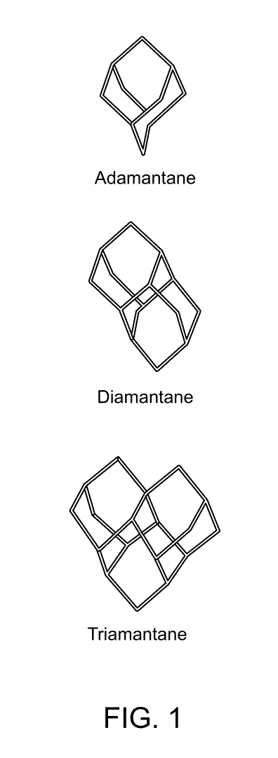

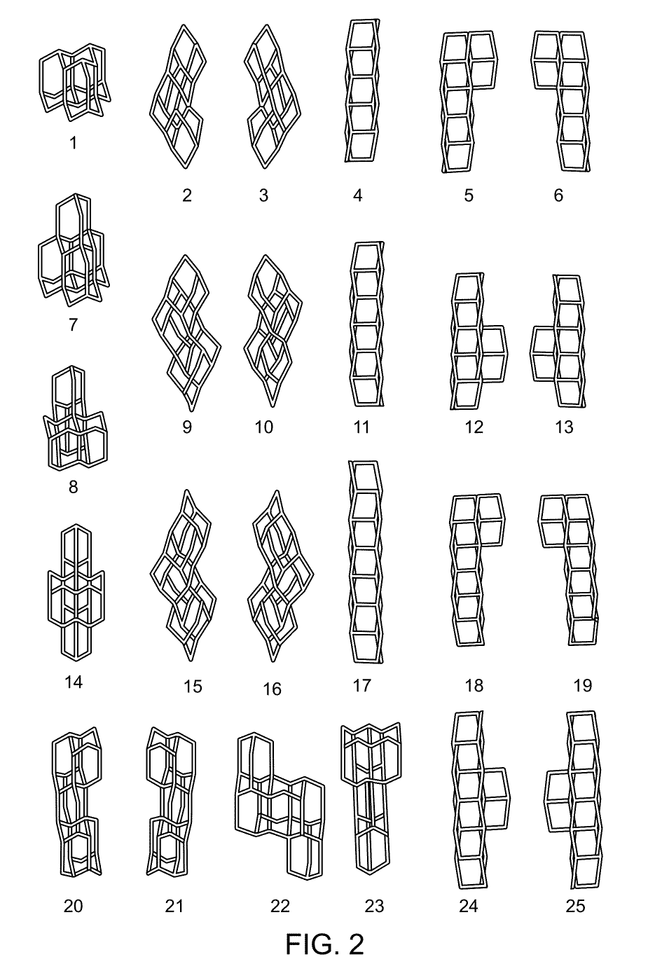

Diamondoids include lower diamondoids, which include adamantane, diamantane, and triamantane, and are composed of 1, 2, and 3 diamond crystal cages respectively as shown in FIG. 1. Diamondoids also include higher diamondoids, which are composed of 4 or more diamond crystal cages, such as 4 to 11 or more diamond crystal cages. Examples of higher diamondoids include tetramantane, pentamantane, hexamantane, heptamantane, octamantane, nonamantane, decamantane, undecamantane, as well as isomers and stereoisomers thereof. FIG. 2 shows selected examples of higher diamondoids. As shown in FIG. 1 and FIG. 2, a diamondoid molecule is composed of carbon-carbon bonds and is hydrogen terminated at its surface.

Diamondoids, whether lower diamondoids or higher diamondoids, can be un-substituted or substituted. Substituted diamondoids can be chemically functionalized by replacing one or more terminal hydrogen atoms with one or more functional groups. In some embodiments, chemical functionalization of diamondoids allows for covalent bonding to a variety of substrates for seeded growth of diamond. A suitable functional group can be selected according to a desired target substrate for diamond growth. Examples of substituted diamondoids include:

(1) Thiol-functionalized diamondoids, in which one or more terminal hydrogen atoms are replaced with one or more functional groups selected from —SH (thiol group) and -L-SH, where L is a linking group such as a C₁-C₁₀ alkylene group, a C₂-C₁₀ alkenylene group, or a C₂-C₁₀ alkynylene group.

(2) Carboxy-functionalized diamondoids, in which one or more terminal hydrogen atoms are replaced with one or more functional groups selected from —COOH (carboxy group) and -L-COOH, where L is a linking group such as a C₁-C₁₀ alkylene group, a C₂-C₁₀ alkenylene group, or a C₂-C₁₀ alkynylene group.

(3) Halo-functionalized diamondoids, in which one or more terminal hydrogen atoms are replaced with one or more functional groups selected from —X (halo group, such as fluoro, chloro, bromo, or iodo) and -L-X, where L is a linking group such as a C₁-C₁₀ alkylene group, a C₂-C₁₀ alkenylene group, or a C₂-C₁₀ alkynylene group.

(4) Hydroxy-functionalized diamondoids, in which one or more terminal hydrogen atoms are replaced with one or more functional groups selected from —OH (hydroxy group) and -L-OH, where L is a linking group such as a C₁-C₁₀ alkylene group, a C₂-C₁₀ alkenylene group, or a C₂-C₁₀ alkynylene group.

(5) Cyano-functionalized diamondoids, in which one or more terminal hydrogen atoms are replaced with one or more functional groups selected from —CN (cyano group) and -L-CN, where L is a linking group such as a C₁-C₁₀ alkylene group, a C₂-C₁₀ alkenylene group, or a C₂-C₁₀ alkynylene group.

(6) Nitro-functionalized diamondoids, in which one or more terminal hydrogen atoms are replaced with one or more functional groups selected from —NO₂ (nitro group) and -L-NO₂, where L is a linking group such as a C₁-C₁₀ alkylene group, a C₂-C₁₀ alkenylene group, or a C₂-C₁₀ alkynylene group.

(7) Amino-functionalized diamondoids, in which one or more terminal hydrogen atoms are replaced with one or more functional groups selected from —NH₂ (amino group) and -L-NH₂, where L is a linking group such as a C₁-C₁₀ alkylene group, a C₂-C₁₀ alkenylene group, or a C₂-C₁₀ alkynylene group.

(8) Silyl-functionalized diamondoids, in which one or more terminal hydrogen atoms are replaced with one or more functional groups selected from —SiR⁽¹⁾R⁽²⁾R⁽³⁾, where R⁽¹⁾, R⁽²⁾, and R⁽³⁾ are independently selected from a hydride group, a halo group, a hydroxy group, an alkyl group, an alkenyl group, and an alkynyl group. An example of a silyl-functionalized diamondoid is a silanol-functionalized diamondoid, in which at least one terminal hydrogen atom is replaced with —Si(OH)₃. Another example of a silyl-functionalized diamondoid is one in which R⁽¹⁾, R⁽²⁾, and R⁽³⁾ are independently selected from a halo group and a hydroxy group.

(9) Phosphoryl-functionalized diamondoids, in which one or more terminal hydrogen atoms are replaced with one or more functional groups selected from —(P═O)R⁽¹⁾R⁽²⁾, where R⁽¹⁾ and R⁽²⁾ are independently selected from a hydride group, a halo group, a hydroxy group, an alkyl group, an alkenyl group, and an alkynyl group. An example of a phosphoryl-functionalized diamondoid is one in which R⁽¹⁾ and R⁽²⁾ are independently selected from a halo group and a hydroxy group.

(10) Sulfonic acid-functionalized diamondoids, in which one or more terminal hydrogen atoms are replaced with one or more functional groups selected from —SO₂R, where R is selected from a hydride group, a halo group, a hydroxy group, an alkyl group, an alkenyl group, and an alkynyl group. An example of a sulfonic acid-functionalized diamondoid is one in which R is selected from a halo group and a hydroxy group.

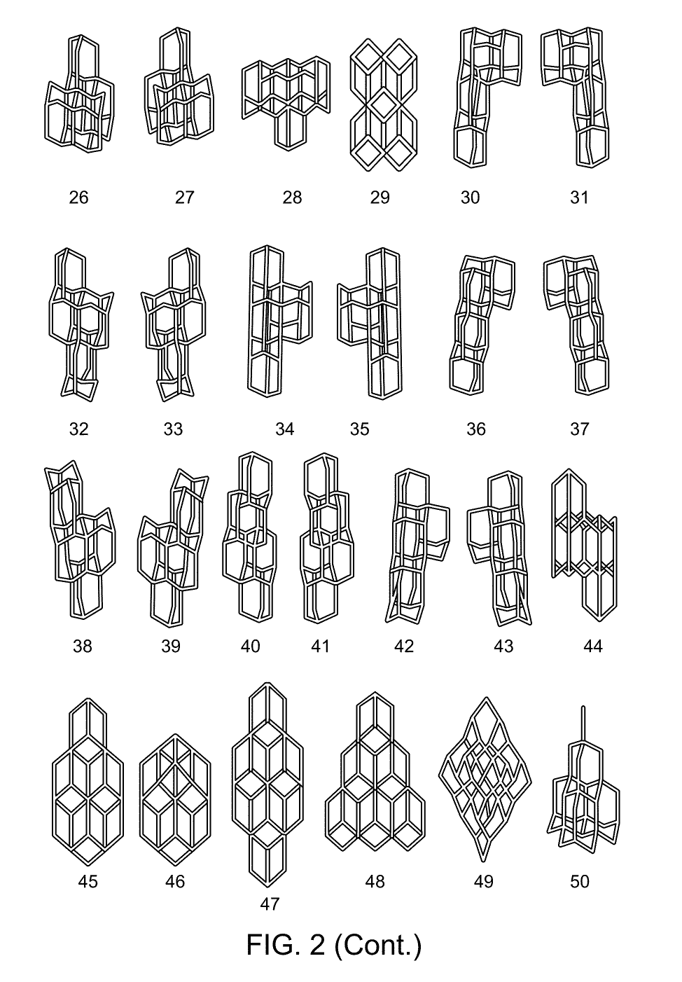

Chemically functionalization of a diamondoid can be performed at or near a top of the molecule, yielding an apical-functionalized diamondoid, at or near a base of the molecule, yielding a medial-functionalized diamondoid, or at another location or a combination of different locations along the molecule. FIG. 3 shows selected examples of apical-functionalized diamondoids and medial-functionalized diamondoids. Although chemical functionalization with thiol groups are shown in FIG. 3, it is contemplated that a diamondoid can be chemically functionalized with another function group or a combination of different functional groups.

Diamondoids, whether lower diamondoids or higher diamondoids, can be un-doped or doped. Doping of diamondoids can be performed by replacing one or more carbon atoms with one or more heteroatoms, such as boron, nitrogen, silicon, sulfur, oxygen, and phosphorus atoms.

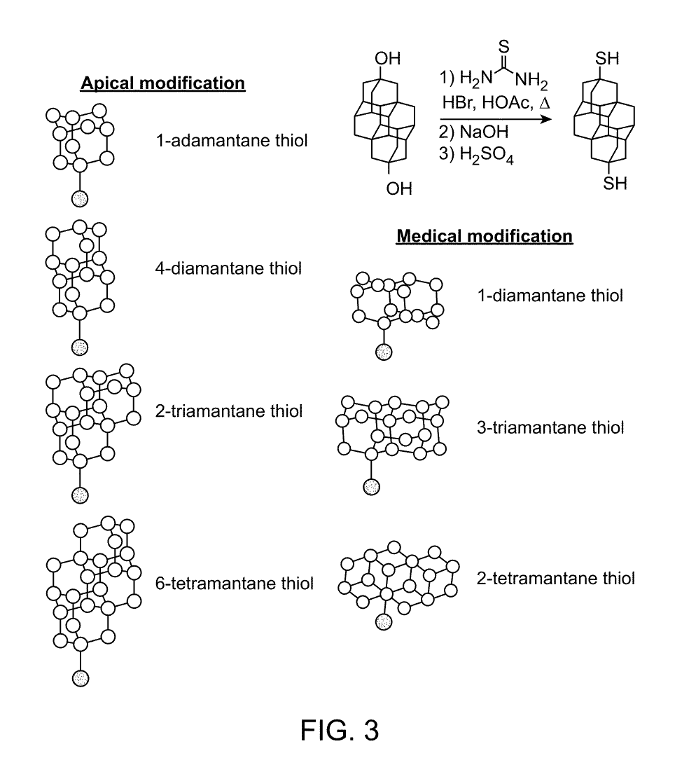

FIG. 4 shows a sequence of operations of a method of growing diamond of an embodiment of this disclosure. Referring first to FIG. 4A, diamondoids 400 are chemically functionalized, and are anchored or bonded to a substrate 402 to form a monolayer of the diamondoids 400 as a seeding layer for subsequent diamond growth. In the illustrated embodiment, bonding between the diamondoids 400 and the substrate 402 is via covalent bonds, although other types of chemical bonds are contemplated, such as chemisorptive bonds, ionic bonds, van der Waals bonds, and hydrogen bonds. Chemical bonding and, in particular, covalent bonding promote the formation of a stable seeding layer by allowing the diamondoids 400 to remain intact during subsequent diamond growth conditions and to act as nucleation sites.

The substrate 402 can be formed of a metal, such as gold or another noble metal; a semiconductor, such as silicon or gallium arsenide; an oxide, such as silicon oxide (e.g., SiO₂), tungsten oxide (e.g., WO₃), or another metal or non-metal oxide; or a combination of such materials. The substrate 402 can be a single-layered substrate, or can be multi-layered, such as including a base and a bonding layer disposed over the base, where the bonding layer forms covalent bonds with the chemically functionalized diamondoids 400. An example of such a multi-layered substrate includes a silicon base, such as a silicon wafer, and an oxide layer disposed over the silicon base, such as a silicon oxide layer.

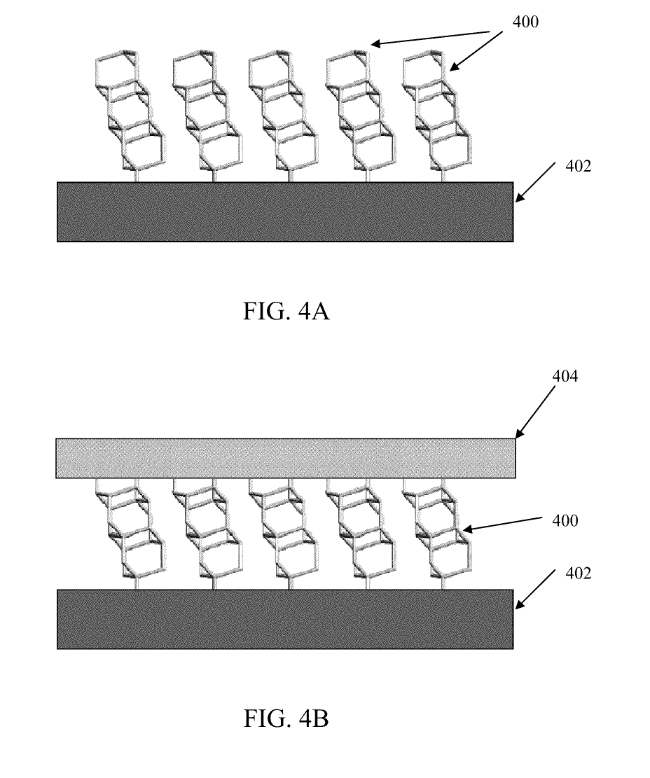

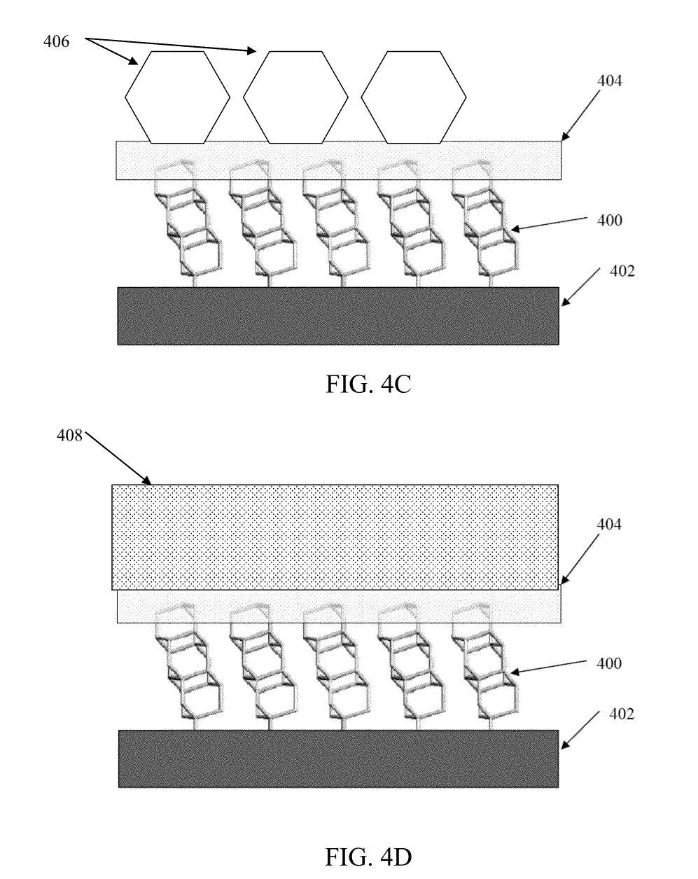

Chemical bonding of diamondoids to a surface can be attained via a number of mechanisms. One example of attaining such chemical bonding is via silylation reactions, such as involving condensation reactions between silanol groups of diamondoids and hydroxy groups exposed on an oxidized silicon surface, as shown in FIG. 5. Resulting chemical bonds between the diamondoids and the surface involve —Si—O— linkages. Another example of attaining such chemical bonding is via reactions between phosphoryl groups of diamondoids and hydroxy groups exposed on an oxide surface, as shown in FIG. 6. Resulting chemical bonds between the diamondoids and the surface involve —P—O— linkages. A further example involves chemical bonding between thiol groups of diamondoids and a metal surface, such as a gold surface. Other suitable chemical bonding mechanisms can be used, such as involving —C—O— linkages, —S—O— linkages, —CO—O— linkages, or a combination of such linkages.

Chemical bonding of diamondoids to a surface can be performed so as to control orientations of the diamondoids and control surfaces of the diamondoids that are exposed for subsequent diamond growth. For example, diamondoids can be chemically bonded to a substrate so as to expose the diamond (111) facet, the diamond (110) facet, the diamond (100) facet, or a combination of such facets.

Because the quality of diamond growth is a function of seeding density, diamondoids, with their small and substantially uniform sizes, promote a high seeding density and a greater uniformity in diamond growth. Referring back to FIG. 4A, a high seeding density is attained by a high packing density of the diamondoids 400 that are anchored to the substrate 402, while reducing a variation of the packing density of the diamondoids 400 across the substrate 402. Chemical bonding of the diamondoids 400 to the substrate 402 promotes a stable packing structure by allowing the diamondoids 400 to remain intact during subsequent diamond growth conditions and to act as nucleation sites. In such manner, a seeding density of the diamondoids 400 can exceed about 10¹¹ cm⁻², such at least or greater than about 3×10¹¹ cm⁻², at least or greater than about 5×10¹¹ cm⁻², at least or greater than about 8×10¹¹ cm⁻², at least or greater than about 1×10¹² cm⁻², at least or greater than about 3×10¹² cm⁻², at least or greater than about 5×10¹² cm⁻², at least or greater than about 8×10¹² cm⁻², and up to about 10¹³ cm⁻², up to about 10¹⁴ cm⁻², or more. Also, a seeding density of the diamondoids 400 can exhibit a low variation across at least a portion of the substrate 402, with a standard deviation that is no greater than about 40% relative to an average seeding density across the portion of the substrate 402, such as no greater than about 35%, no greater than about 30%, no greater than about 25%, no greater than about 20%, no greater than about 15%, or no greater than about 10%, and down to about 5%, down to about 2%, down to about 1%, or less. The high seeding density and high uniformity in the seeding density promote effective nucleation and greater uniformity in diamond growth with superior mechanical, thermal, optical, and electronic characteristics. The substantially defect- and impurity-free nature of the diamondoids 400 further promotes diamond growth with high quality and high uniformity.

Next, referring to FIG. 4B, a coating or layer 404 is formed over the diamondoids 400 to serve a protective function for the diamondoids 400 during subsequent diamond growth conditions. In conjunction with chemical bonding of the diamondoids 400 to the substrate 402, the protective coating 404 protects the diamondoids 400 against an etching effect during subsequent diamond growth, such as an etching effect of plasma during PECVD, which otherwise can lead to removal of the diamondoids 400 or introduce surface defects in the diamondoids 400. In the illustrated embodiment, the protective coating 404 is formed of an oxide, such as titanium oxide (e.g., TiO₂), aluminum oxide (e.g., Al₂O₃), another metal or non-metal oxide, or a combination of such oxides, and is formed over the diamondoids 400 using Physical Vapor Deposition (“PVD”), such as thermal evaporation, sputtering, pulsed laser deposition, or cathodic arc deposition. It is contemplated that the protective coating 404 can be formed of other materials, such as metal or non-metal nitrides and other ceramics or dielectrics, and other suitable deposition techniques can be used. A thickness of the protective coating 404 can be in the range of about 0.5 nm to about 15 nm, such as from about 0.5 nm to about 10 nm, from about 0.5 nm to about 5 nm, or from about 1 nm to about 3 nm.

Next, referring to FIG. 4C and FIG. 4D, diamond growth is carried out over the protective coating 404 and the diamondoids 400 to form diamond nanoparticles 406 (as shown in FIG. 4C) or a diamond film 408 (as shown in FIG. 4D). In the illustrated embodiment, diamond growth can be viewed as nanometer-scale heteroepitaxy over the substrate 402, and is performed using Chemical Vapor Deposition (“CVD”) and, in particular, PECVD. According to PECVD, an electrical current or a microwave excitation is used to produce a plasma including Argon or other inert gas, along with a carbon source, such as methane (CH₄) or another alkane, an alkene, an alkyne, or an arene. PECVD can be performed in a deposition chamber with remote or direct plasma impinging upon the substrate 402, thereby inducing nucleation and growth of diamond. Using diamondoid seeding, diamond growth can be performed by PECVD at moderate temperatures below about 700° C., such as no greater than about 650° C., no greater than about 600° C., no greater than about 550° C., no greater than about 500° C., no greater than about 450° C., no greater than about 400° C., no greater than about 350° C., or no greater than about 300° C., and down to about 250° C., down to about 200° C., or less, rendering this technique compatible with electronic devices and semiconductor processing technologies. It is contemplated that other suitable deposition techniques can be used for diamond growth, such as other CVD techniques. It is also contemplated that the protective coating 404 can be at least partially removed during diamond growth, such as a result of the etching effect of plasma during PECVD, while serving its protective function for the diamondoids 400.

Growth conditions, such as growth time, can be adjusted to form the diamond nanoparticles 406 (as shown in FIG. 4C) or the diamond film 408 (as shown in FIG. 4D). In the case of FIG. 4C, the diamond nanoparticles 406 can be ultra-small diamond nanoparticles having sizes below about 5 nm, such as up to about 4.9 nm, up to about 4.7 nm, up to about 4.5 nm, up to about 4.3 nm, up to about 4.1 nm, up to about 3.9 nm, or up to about 3.7 nm, and down to about 2 nm, down to about 1 nm, or less, although diamond nanoparticles having larger sizes also can be formed in some embodiments. Also, the diamond nanoparticles 406 can have a high degree of uniformity in sizes, with a standard deviation in sizes that is no greater than about 50% relative to an average size across a population of the diamond nanoparticles 406, such as no greater than about 45%, no greater than about 40%, no greater than about 35%, no greater than about 30%, no greater than about 25%, or no greater than about 20%, and down to about 10%, down to about 5%, or less. Moreover, the diamond nanoparticles 406 can be substantially free of defects, which can refer to crystal stacking errors, surface defects, vacancies, or impurities, such that, within a population of the diamond nanoparticles 406, there is no more than 1 defect per 10 diamond nanoparticles, such as no more than 1 defect per 50 diamond nanoparticles, no more than 1 defect per 100 diamond nanoparticles, no more than 1 defect per 200 diamond nanoparticles, no more than 1 defect per 500 diamond nanoparticles, no more than 1 defect per 1,000 diamond nanoparticles, no more than 1 defect per 10⁴ diamond nanoparticles, or no more than 1 defect per 10⁵ diamond nanoparticles. For certain applications, NV centers can be incorporated into the diamond nanoparticles 406, such as by nitrogen implantation and annealing at a temperature in the range of about 600° C. to about 1,000° C., such as from about 700° C. to about 900° C. Other types of nanostructures can be formed in place of, or in conjunction with, the diamond nanoparticles 406.

In the case of FIG. 4D, the diamond film 408 can be formed with a high degree of continuity and uniformity, which can correlate with the diamond film 408 being substantially free of pinholes, such as depressions, gaps, or other discontinuities in the diamond film 408. Across at least a portion of the diamond film 408 in some cases, there is no more than 10⁴ pinholes per cm², such as no more than 1,000 pinholes per cm², no more than 500 pinholes per cm², no more than 200 pinholes per cm², no more than 100 pinholes per cm², or no more than about 50 pinholes per cm², and down to about 10 pinholes per cm², down to about 5 pinholes per cm², or less. In other cases, pinholes account for no more than about 10% of a surface area (e.g., as viewed from the top) of at least a portion of the diamond film 408, such as no more than about 5%, no more than about 2%, no more than about 1%, no more than about 0.5%, no more than about 0.1%, and down to about 0.05%, down to about 0.01, or less. The high continuity and uniformity of the diamond film 408 provide a desired thermal, mechanical, or other effect to be attained with a reduced thickness of the film 408, thus significantly reducing growth time down to about 5 hours or less, such as about 4 hours or less, about 3 hours or less, about 2 hours or less, or about 1 hour or less. As such, the diamond film 408 can be an ultra-thin diamond film having a thickness up to about 300 nm, such as up to about 200 nm, up to about 100 nm, up to about 90 nm, up to about 80 nm, up to about 70 nm, up to about 60 nm, up to about 50 nm, up to about 40 nm, or up to about 30 nm, and down to about 20 nm, down to about 10 nm, or less, although diamond films having greater thicknesses also can be formed in some embodiments. For certain applications, dopants, such as boron or other n-type dopants, can be incorporated into the diamond film 408, such as by n-type dopant functionalization.

### EXAMPLES

The following examples describe specific aspects of some embodiments of the invention to illustrate and provide a description for those of ordinary skill in the art. The examples should not be construed as limiting the invention, as the examples merely provide specific methodology useful in understanding and practicing some embodiments of the invention.

### Example 1

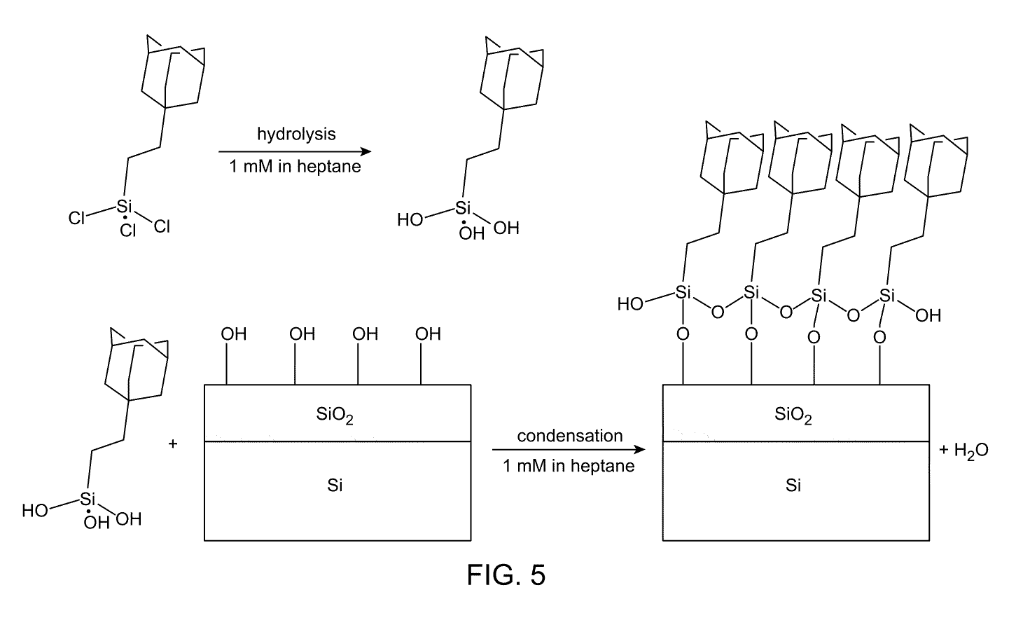

FIG. 7 shows diamonds that were grown by CVD and subjected to Raman spectrum analysis. A 1332 cm⁻¹ peak is a characteristic optical phonon peak for identifying diamond. The inset in FIG. 7 shows a peak at about 1,332 cm⁻¹ confirming the presence of diamond, as well as a peak at about 520 cm⁻¹ for silicon of an underlying substrate. CVD growth conditions were about 1,300 W, about 30 Torr, about 650° C., and for about 1 hour.

### Example 2

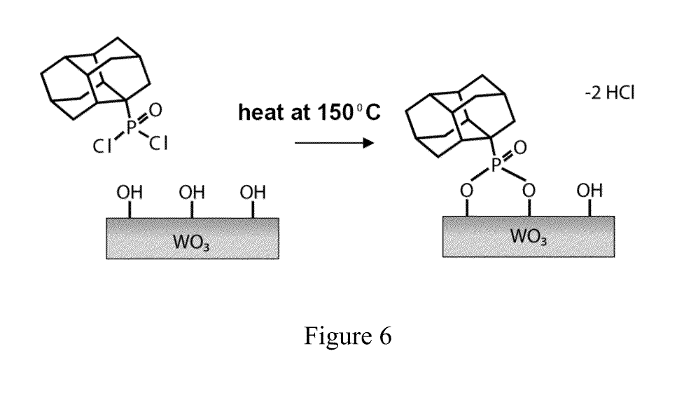

FIG. 8 shows a comparison of diamond growth by CVD using thiol-functionalized diamantane (d) as a seeding molecule, versus other forms of carbon as seeding molecules. The other forms of carbon were dodecanethiol (a), C₆₀ (b), and butanethiol (c). Diamond growth was observed with diamantane, but not with the other forms of carbon. CVD growth conditions were about 500 W, about 30 Ton, about 350° C., CH₄:1% in Ar, and for about 1 hour.

### Example 3

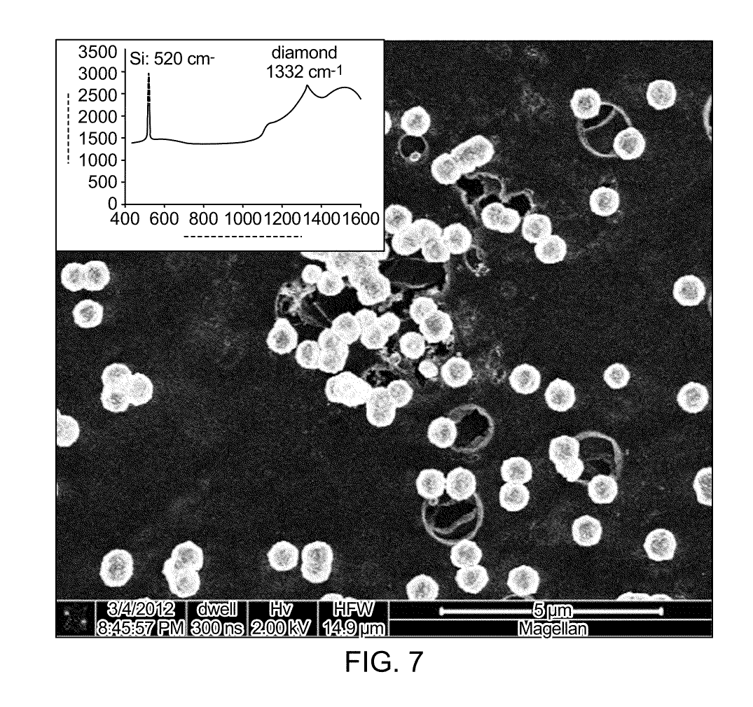

FIG. 9 shows a comparison of diamond growth using adamantane as a seeding molecule, versus UDD seeding. It can be observed that seeding density is higher with diamondoid seeding, and uniformity of diamond growth is improved with diamondoid seeding, thereby allowing the formation of substantially pinhole-free films with thickness of about 20-30 nm. As opposed to UDD seeding, growth with diamondoid seeding yields diamond nanoparticles having a smaller deviation in size under the same CVD conditions, which were about 500 W, about 30 Torr, about 400° C., and for about 1 hour.

### Example 4

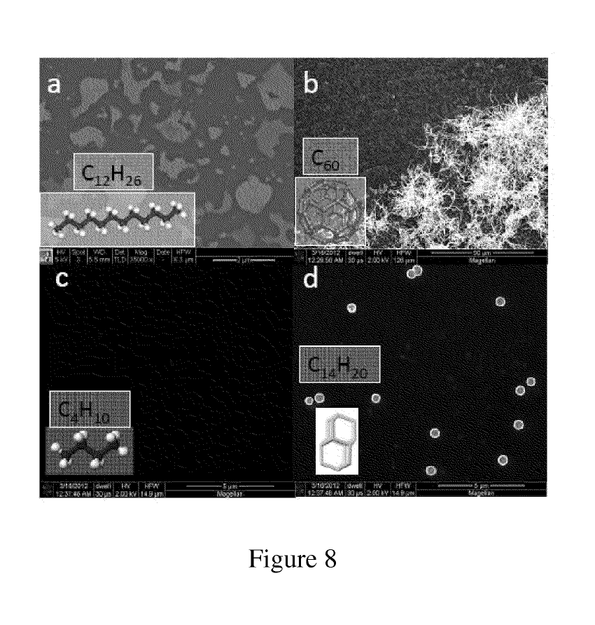

FIG. 10 shows a substantially pinhole-free diamond film formed after about 1 hour of CVD growth. The panel on the left shows a top view of the film, and the panel on the right shows a cross-sectional view for confirmation of thickness, which in this example is about 20 nm. CVD growth conditions were about 500 W, about 30 Torr, about 300° C., and for about 1 hour.

### Example 5

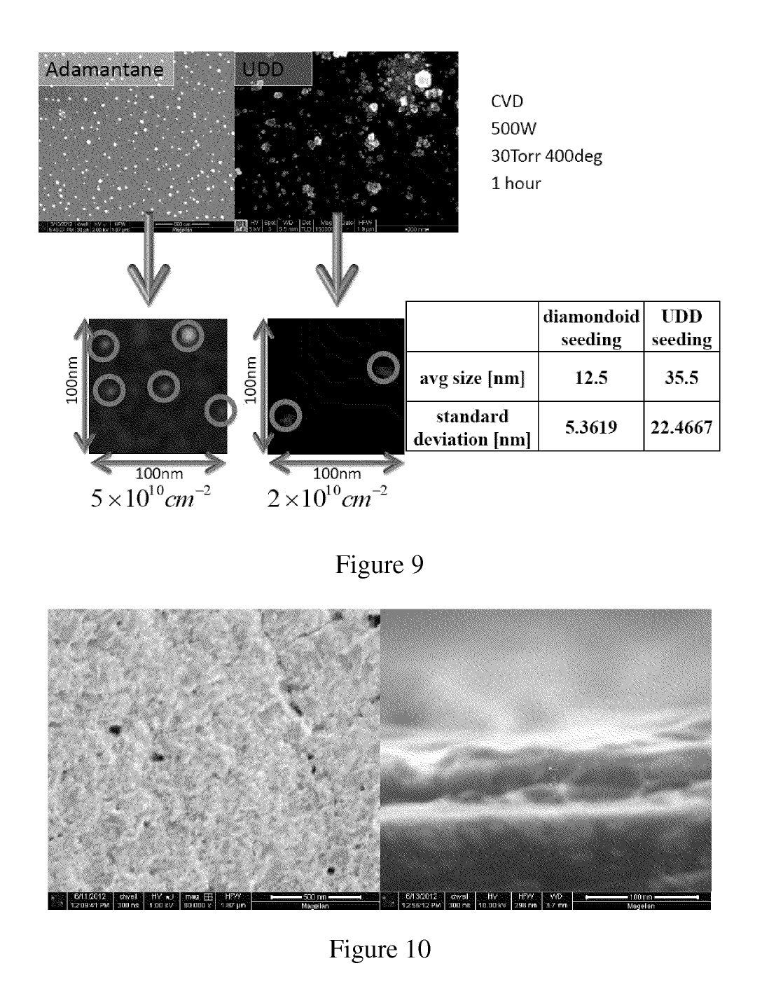

FIG. 11 shows top views of monolayers of thiol-functionalized diamondoids formed over Au substrates. It can be observed that a high seeding density can be attained with the diamondoids as seeding molecules.

### Example 6

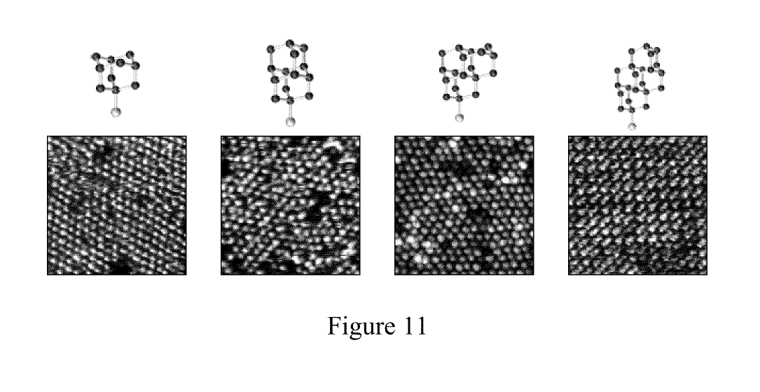

For confirmation of diamond nanoparticle formation, TEM analysis was performed, and results are shown in FIG. 12. The top right panel shows an image of diamond nanoparticles formed of sizes less than about 5 nm, without graphite formation on the outside. The bottom right panel shows a cross-section profile of diamond nanoparticles, indicating a lattice spacing of about 2.06 angstrom, which corresponds to the lattice spacing for the diamond (111) facet. Micro diffraction analysis was also performed on a nanoparticle with a spot size of about 5 nm, and results are shown on the left panel. Specific lattice spacing with specific angle was observed to match with the diamond crystal structure. FIG. 12 shows a case where the z axis was taken to be along (110). CVD growth conditions were about 500 W, about 30 Torr, about 400° C., CH₄:1%, and for about 1 hour using silyl-functionalized adamantane as a seeding molecule.

### Example 7

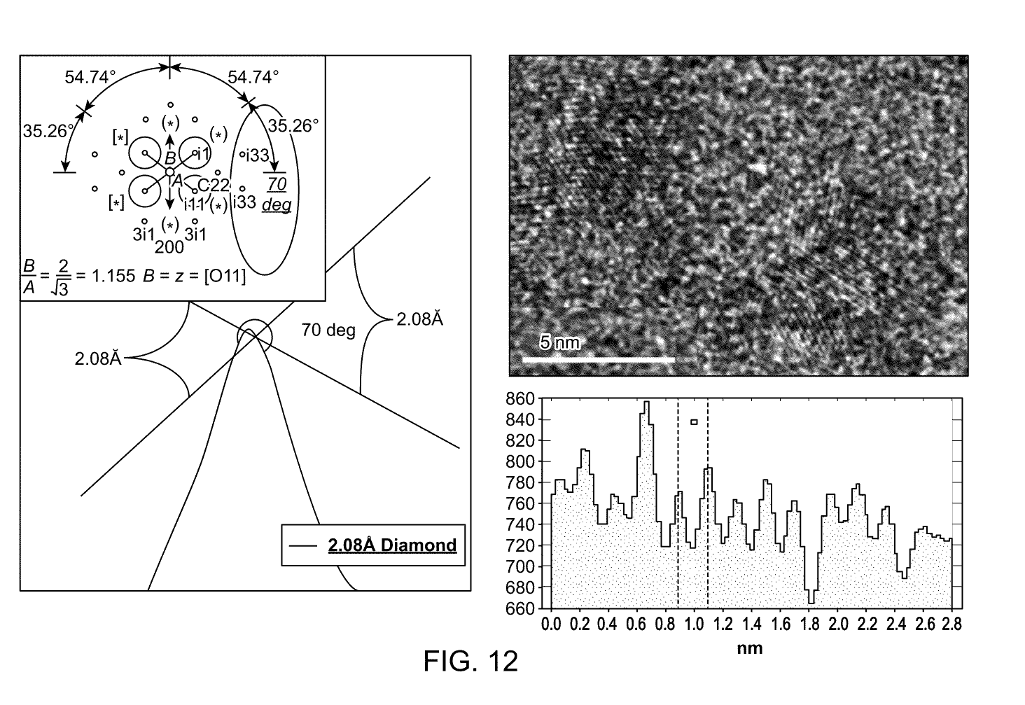

FIG. 13 shows superimposed FTIR spectra to confirm presence of diamondoid after TiO₂ coating. Both of the spectra (before and after TiO₂ coating) show distinctive diamondoid peaks corresponding to CH₂ symmetry and asymmetry modes of vibration.

### Example 8

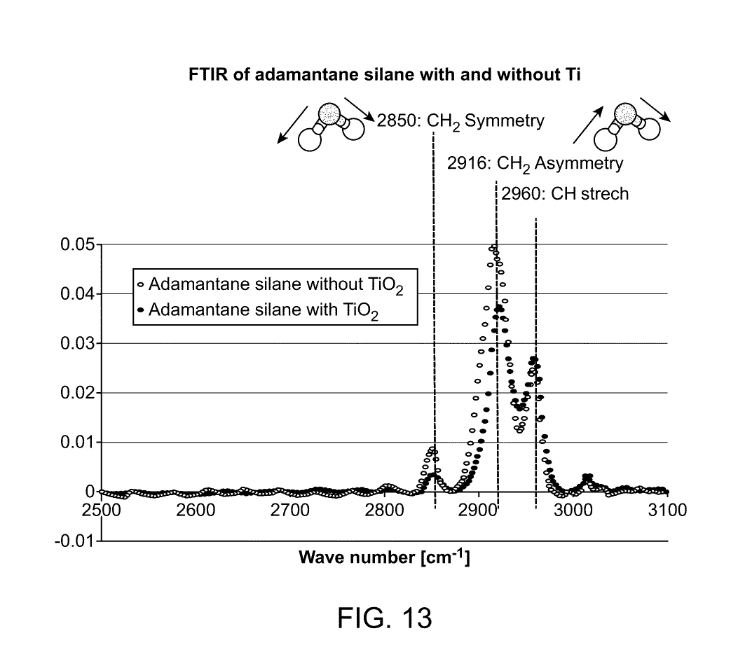

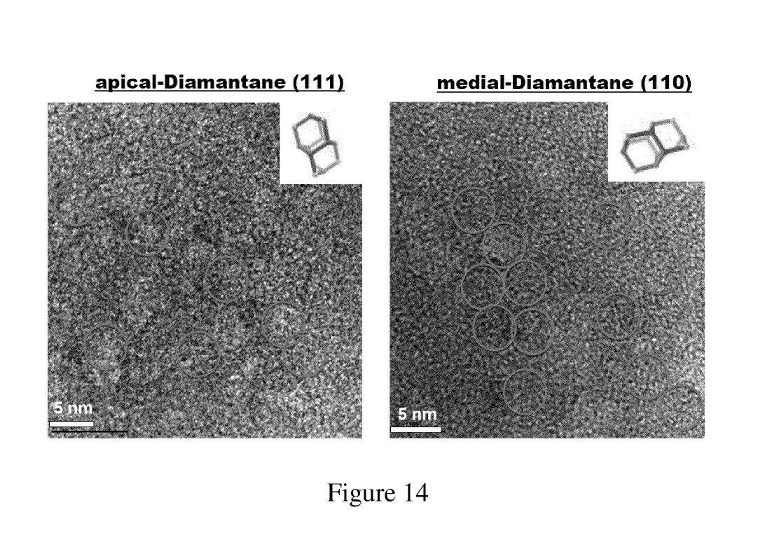

FIG. 14 shows a comparison of diamond growth by CVD using apical-functionalized diamantane versus medial-functionalized diamantane as seeding molecules. Nucleation was modest with apical-functionalized diamantane, while the extent of nucleation was about two times greater with medial-functionalized diamantane. Nanoparticles that were formed had sizes less than about 5 nm. CVD growth conditions were about 300 W, about 30 Torr, about 300° C., about 6% CH₄ in Ar plasma, using a Ti-containing protective coating of about 3 nm in thickness, and for about 1 hour. FIG. 15 shows a comparison of diamond growth by CVD using apical-functionalized tetramantane versus basal-functionalized pentamantane as seeding molecules under similar CVD growth conditions.

### Example 9

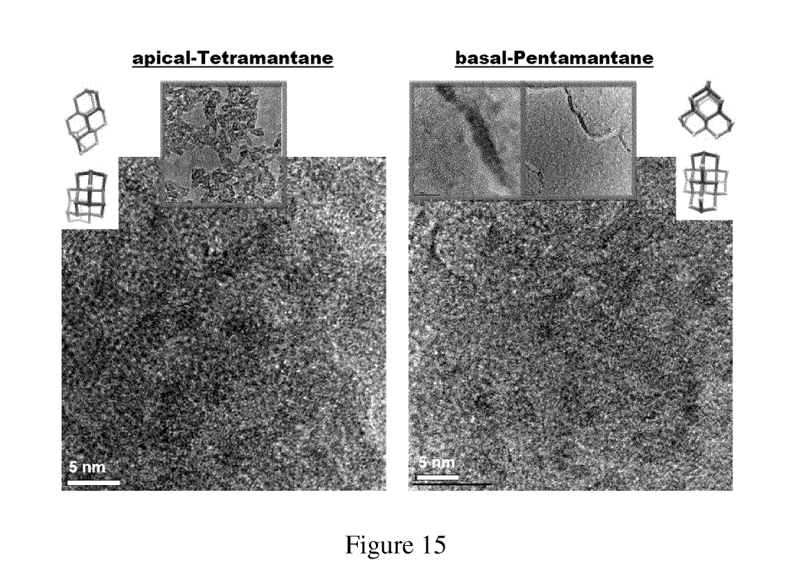

FIG. 16 shows a bright field image of diamond growth on a SiO₂ window grid using diamondoid seeding. Diamond nanoparticles having diameters in the range of about 3-6 nm were observed, along with a lattice fringe of about 0.204 nm. Little evidence of graphite was observed.

### Example 10

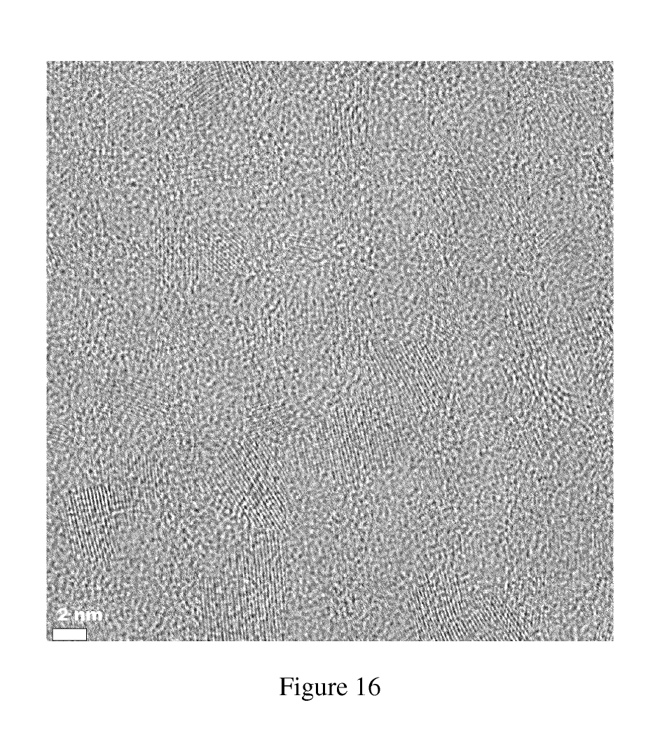

FIG. 17 shows a TEM image of diamond growth using diamondoid seeding. Seeding density was about 5×10¹² cm³. The superimposed rectangular area includes 40 diamond nanoparticles having an average diameter of about 3.97±0.4 nm.

### Example 11

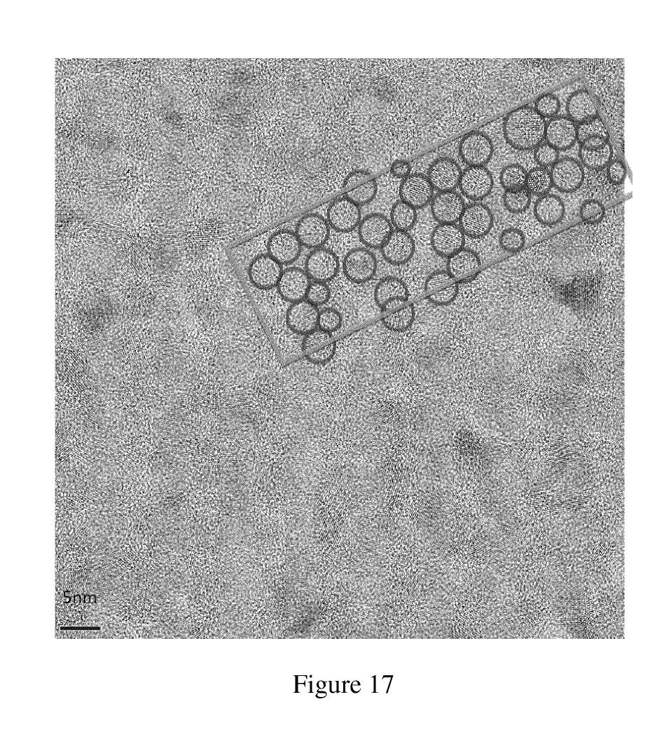

FIG. 18 shows diamond nanoparticles after implantation with nitrogen and annealing at about 800° C. The image demonstrates that diamond nanoparticles produced through diamondoid seeding can survive the implantation process, thus allowing the formation of substantially defect-free NV centers in diamond nanoparticles.

### Example 12

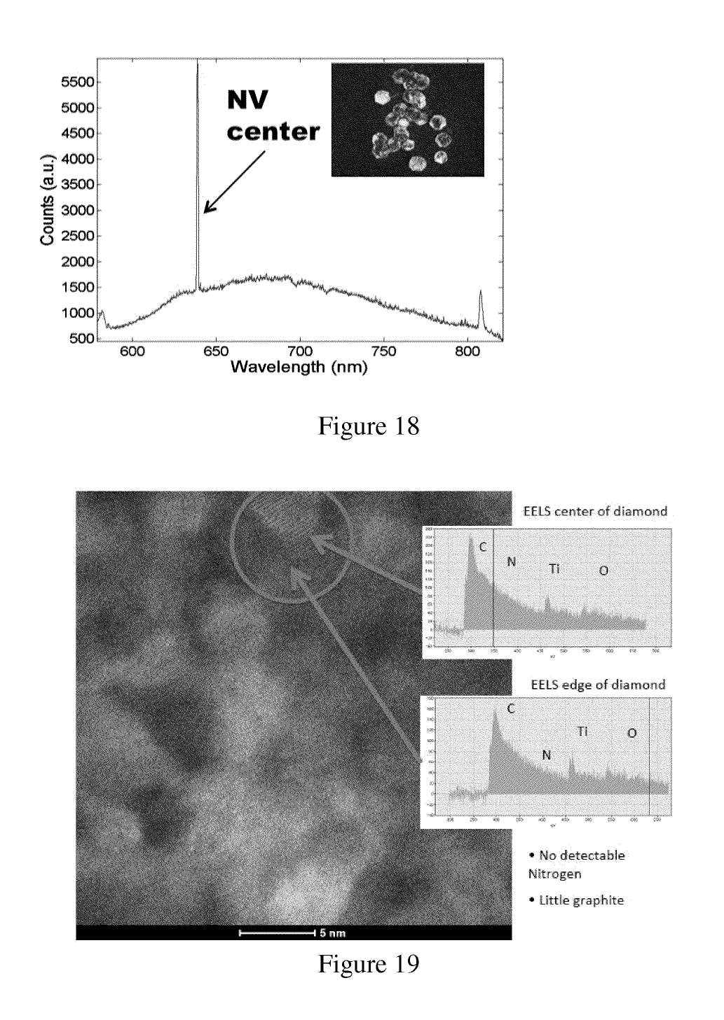

For confirmation of diamond nanoparticle formation, EELS analysis was performed, and results are shown in FIG. 19. The EELS analysis shows a very strong sigma carbon peak at about 290 eV, which indicates the presence of sp³ carbon and therefore diamond. And the EELS analysis shows no detectable presence of nitrogen, which demonstrates that diamond nanoparticles grown from diamondoids are substantially nitrogen free.

### Example 13

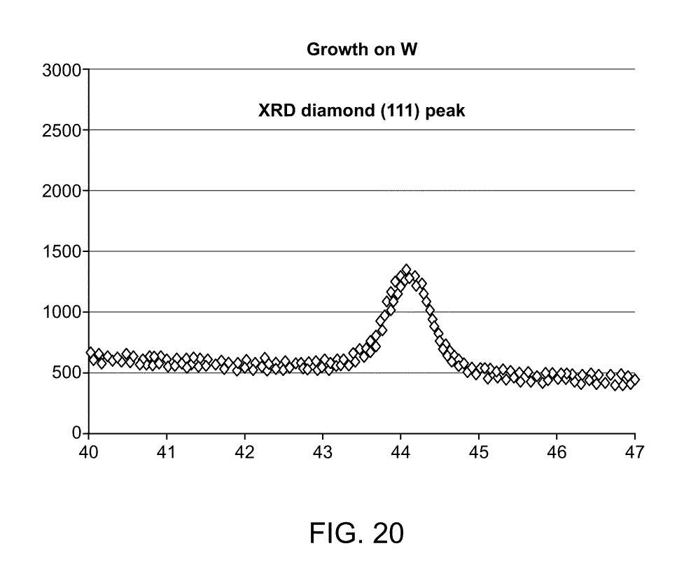

FIG. 20 shows a XRD spectrum obtained from diamond grown on a tungsten substrate using diamantane functionalized with phosphoric dichloride. The XRD spectrum demonstrates that diamond is formed and also demonstrates the capability of growing diamond on other metals.

While the invention has been described with reference to the specific embodiments thereof, it should be understood by those skilled in the art that various changes may be made and equivalents may be substituted without departing from the true spirit and scope of the invention as defined by the appended claims. In addition, many modifications may be made to adapt a particular situation, material, composition of matter, method, operation or operations, to the objective, spirit and scope of the invention. All such modifications are intended to be within the scope of the claims appended hereto. In particular, while certain methods may have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations is not a limitation of the invention.

What is claimed is:

1. A method of growing diamond, comprising:
anchoring diamondoids to a substrate via chemical bonding between the diamondoids and the substrate;
forming a protective layer over the diamondoids; and
performing chemical vapor deposition using a carbon source to induce diamond growth over the protective layer and the diamondoids.

2. The method of claim 1, wherein anchoring the diamondoids to the substrate is performed via covalent bonding between the diamondoids and the substrate.

3. The method of claim 1, wherein the diamondoids are anchored to the substrate via at least one of —Si—O— linkages, —P—O— linkages, —C—O— linkages, —S—O— linkages, and —CO—O— linkages.

4. The method of claim 1, wherein the diamondoids are chemically functionalized to form covalent bonds with the substrate.

5. The method of claim 1, wherein the diamondoids are selected from at least one of thiol-functionalized diamondoids, carboxy-functionalized diamondoids, halo-functionalized diamondoids, hydroxy-functionalized diamondoids, cyano-functionalized diamondoids, nitro-functionalized diamondoids, amino-functionalized diamondoids, silyl-functionalized diamondoids, phosphoryl-functionalized diamondoids, and sulfonic acid-functionalized diamondoids.

6. The method of claim 1, wherein anchoring the diamondoids to the substrate includes forming a monolayer of the diamondoids over the substrate, and a seeding density of the diamondoids across at least a portion of the substrate is greater than 10¹¹ cm⁻².

7. The method of claim 6, wherein the seeding density of the diamondoids is at least 1×10¹² cm⁻².

8. The method of claim 1, wherein the protective layer is formed of an oxide.

9. The method of claim 1, wherein the protective layer is formed of at least one of titanium oxide and aluminum oxide.

10. The method of claim 1, wherein a thickness of the protective layer is in the range of 0.5 nm to 10 nm.

11. The method of claim 1, wherein performing chemical vapor deposition is carried out at a temperature no greater than 650° C.

12. The method of claim 1, wherein performing chemical vapor deposition is carried out at a temperature no greater than 400° C.

13. The method of claim 1, wherein performing chemical vapor deposition includes forming diamond nanoparticles.

14. The method of claim 13, wherein the diamond nanoparticles have sizes below 5 nm.

15. The method of claim 13, wherein a standard deviation in the sizes is no greater than 50% relative to an average size across the diamond nanoparticles.

16. The method of claim 1, wherein performing chemical vapor deposition includes forming a diamond film.

17. The method of claim 16, wherein a thickness of the diamond film is up to 100 nm.

18. The method of claim 16, wherein the diamond film has no more than 10⁴ pinholes per cm² of the diamond film.

19. A diamond nanoparticle formed according to the method of claim 1.

20. A diamond film formed according to the method of claim 1.
